(19) United States
(12) Patent Application Publication
(10) Pub. No.: US 2026/0080909 A1
(43) Pub. Date: Mar. 19, 2026

(54) SEMICONDUCTOR MEMORY DEVICE AND METHOD OF MANUFACTURING THE SAME

(71) Applicant: Kioxia Corporation, Tokyo (JP)

(72) Inventors: Yutaro OGAWA, Kawasaki Kanagawa (JP); Masayasu MIYATA, Kawasaki Kanagawa (JP)

(73) Assignee: Kioxia Corporation, Tokyo (JP)

(21) Appl. No.: 19/069,531

(22) Filed: Mar. 4, 2025

(30) Foreign Application Priority Data
Sep. 18, 2024 (JP) 2024-160931

(51) Int. Cl. G11C 5/06; G11C 16/04; H01L 23/00; H10B 41/10; H10B 41/27; H10B 43/10; H10B 43/27; H10D 62/60

(52) U.S. Cl. CPC G11C 5/063; G11C 16/0483; H10B 41/10; H10B 41/27; H10B 43/10; H10B 43/27; H10D 62/60; H10W 90/791

(57) ABSTRACT

A semiconductor memory device includes: a plurality of first conductive layers arranged in a first direction and extending in a second direction intersecting with the first direction and a third direction intersecting with the first direction and the second direction; and a memory structure extending in the first direction, the memory structure including a first semiconductor layer opposed to the plurality of first conductive layers and a gate insulating layer disposed between the first semiconductor layer and the plurality of first conductive layers. The first semiconductor layer contains single-crystallized silicon and an impurity. The impurity contain: a first metallic element that is able to form silicide; and a second metallic element constituting a metal material having a linear expansion coefficient larger than a linear expansion coefficient of a silicon material.

### CROSS-REFERENCE TO RELATED APPLICATIONS

This application is based upon and claims the benefit of Japanese Patent Application No. 2024-160931, filed on Sep. 18, 2024, the entire contents of which are incorporated herein by reference.

### BACKGROUND

### Field

Embodiments described herein relate generally to a semiconductor memory device and a method of manufacturing the same.

### Description of the Related Art

There has been known a semiconductor memory device that includes a substrate, a plurality of conductive layers stacked in a direction intersecting with a surface of this substrate, a semiconductor layer opposed to these plurality of conductive layers, and a gate insulating layer disposed between the conductive layers and the semiconductor layer. The gate insulating layer includes a memory portion that can store data, and the memory portion is, for example, an insulating electric charge accumulating layer, or a conductive electric charge accumulating layer such as a floating gate.

### BRIEF DESCRIPTION OF THE DRAWINGS

FIG. 1 is a schematic circuit diagram illustrating a configuration of a memory die MD according to a first embodiment;

FIG. 2 is a schematic perspective view illustrating the configuration of the memory die MD;

FIG. 3 is a schematic bottom view illustrating a configuration of a chip C_{M};

FIG. 4 is a schematic bottom view illustrating a configuration of a part of the chip C_{M};

FIG. 5 is a schematic cross-sectional view illustrating a configuration of a part of the memory die MD;

FIG. 6 is a schematic cross-sectional view illustrating a configuration of a part of FIG. 5;

FIG. 7 is a schematic cross-sectional view for describing a method of manufacturing a semiconductor memory device according to the first embodiment;

FIG. 8 is a schematic cross-sectional view for describing the manufacturing method;

FIG. 9 is a schematic cross-sectional view for describing the manufacturing method;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13A, FIG. 13B, and FIG. 13C are schematic cross-sectional views for describing the manufacturing method;

FIG. 14 is a graph for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method; and

FIG. 29 is a schematic cross-sectional view for describing a manufacturing method of a semiconductor memory device according to a second embodiment.

### DETAILED DESCRIPTION

A semiconductor memory device according to one embodiment comprises: a plurality of first conductive layers arranged in a first direction and extending in a second direction intersecting with the first direction and a third direction intersecting with the first direction and the second direction; and a memory structure extending in the first direction, the memory structure including a first semiconductor layer opposed to the plurality of first conductive layers and a gate insulating layer disposed between the first semiconductor layer and the plurality of first conductive layers. The first semiconductor layer contains single-crystallized silicon and an impurity. The impurity contain: a first metallic element that is able to form silicide; and a second metallic element constituting a metal material having a linear expansion coefficient larger than a linear expansion coefficient of a silicon material. Next, the semiconductor memory devices and methods of manufacturing the same according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a predetermined plane may be referred to as a first direction, a direction along this predetermined plane may be referred to as a second direction, and a direction along this predetermined plane and intersecting with the second direction may be referred to as a third direction. These first direction, second direction, and third direction may each correspond to any of the Z-direction, the Y-direction, and the X-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

### First Embodiment

### [Circuit Configuration]

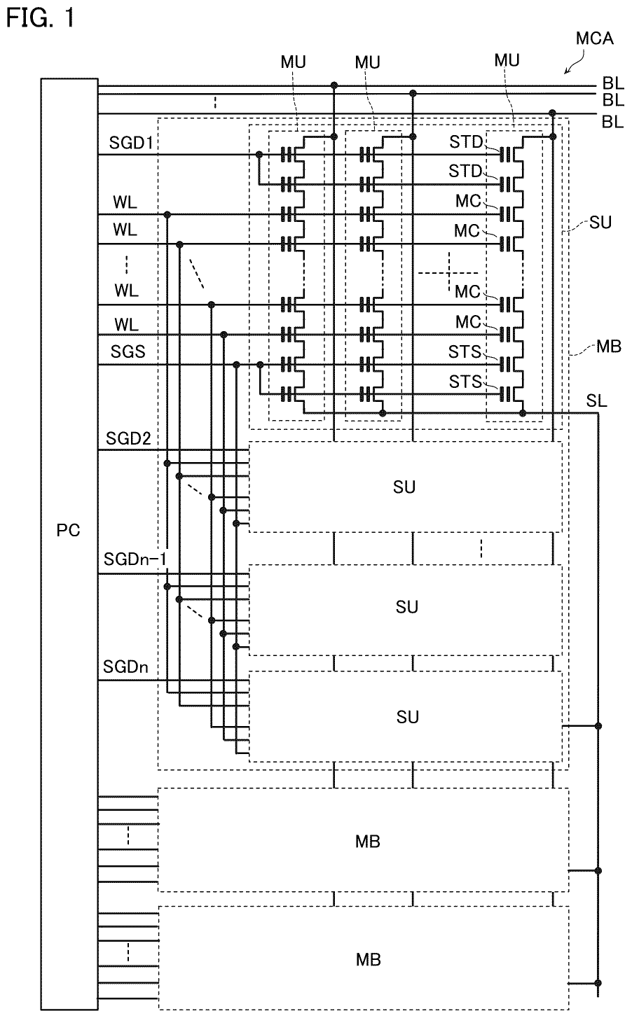

FIG. 1 is an equivalent circuit diagram schematically illustrating a configuration of a semiconductor memory device according to the first embodiment.

The semiconductor memory device according to the embodiment includes a memory cell array MCA and a peripheral circuit PC controlling the memory cell array MCA.

The memory cell array MCA includes a plurality of memory blocks MB. Each of these plurality of memory blocks MB includes a plurality of string units SU. These plurality of string units SU each include a plurality of memory units MU. These plurality of memory units MU have one ends each connected to the peripheral circuit PC via a bit line BL. These plurality of memory units MU have the other ends each connected to the peripheral circuit PC via a common source line SL.

The memory unit MU includes one or a plurality of drain select transistors STD, a plurality of memory cells MC, and one or a plurality of source select transistors STS, which are connected in series between the bit line BL and the source line SL. Hereinafter, the drain select transistor STD and the source select transistor STS may be simply referred to as select transistors (STD, STS) or the like.

The memory cell MC is a field-effect type transistor (memory transistor) that includes a semiconductor layer, a gate insulating film, and a gate electrode. The semiconductor layer functions as a channel region. The gate insulating film includes a memory portion that is able to store data. This memory portion is an electric charge accumulating film, such as a silicon nitride film (SiN) or a floating gate. The memory cell MC has a threshold voltage that changes corresponding to an electric charge amount in the electric charge accumulating film. Respective word lines WL are connected to the gate electrodes of the plurality of memory cells MC included in one memory unit MU. Each of these word lines WL is connected to the memory cells MC at the same position in a series direction of all the memory units MU in one memory block MB in common.

The select transistors (STD, STS) are field-effect type transistors each including a semiconductor layer that functions as a channel region, a gate insulating film, and a gate electrode. While this example is illustrated such that one memory unit MU includes two drain select transistors STD and two source select transistors STS, the respective numbers of the select transistors STD, STS provided in one memory unit MU may be one, or may be three or more. Select gate lines (SGD, SGS) are connected to the gate electrodes of the select transistors (STD, STS), respectively.

The drain select gate line SGD is separately provided for each of the string units SU, and connected to all the drain select transistors STD in one string unit SU in common. In FIG. 1, the drain select gate lines SGD connected to the respective string units SU are illustrated as drain select gate lines SGD1, SGD2, . . . , SGDn-1, and SGDn. The source select gate line SGS is connected to all the source select transistors STS in one memory block MB in common.

### [Structure of Memory Die MD]

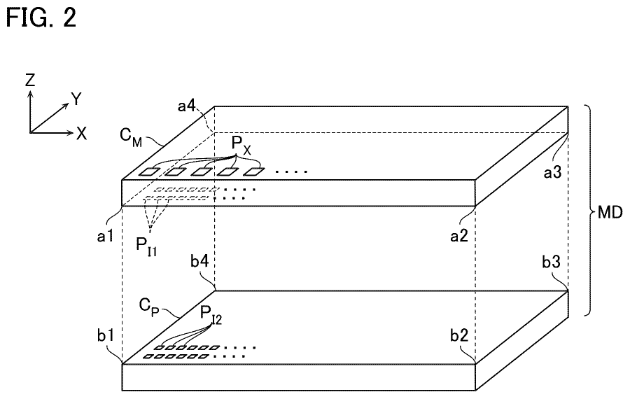

FIG. 2 is a schematic exploded perspective view illustrating an exemplary configuration of the semiconductor memory device according to the embodiment. The semiconductor memory device according to the embodiment includes a memory die MD. The memory die MD includes a chip C_{M} including the memory cell array MCA and a chip C_{P} including the peripheral circuit PC.

On an upper surface of the chip C_{M}, a plurality of bonding pad electrodes P_{X} are disposed. On a lower surface of the chip C_{M}, a plurality of first bonding electrodes P_{I1} are disposed. On an upper surface of the chip C_{P}, a plurality of second bonding electrodes P_{I2} are disposed. Hereinafter, in the chip C_{M}, the surface on which the plurality of first bonding electrodes P_{I1} are disposed is referred to as a front surface, and the surface on which the plurality of bonding pad electrodes P_{X} are disposed is referred to as a back surface. In the chip C_{P}, the surface on which the plurality of second bonding electrodes P_{I2} are disposed is referred to as a front surface, and a surface in the opposite side of the front surface is referred to as a back surface. In the illustrated example, the front surface of the chip C_{P} is disposed above the back surface of the chip C_{P}, and the back surface of the chip C_{M} is disposed above the front surface of the chip C_{M}.

The chip C_{M} and the chip C_{P} are disposed such that the front surface of the chip C_{M} is opposed to the front surface of the chip C_{P}. The plurality of first bonding electrodes P_{I1} are disposed corresponding to the respective plurality of second bonding electrodes P_{I2}, and disposed at positions allowing bonding to the plurality of second bonding electrodes P_{I2}. The first bonding electrode P_{I1} and the second bonding electrode P_{I2} function as bonding electrodes that bond the chip C_{M} and the chip C_{P} together and electrically conduct the chip C_{M} and the chip C_{P}. The bonding pad electrode P_{X} functions as an electrode for electrically connecting the memory die MD to a controller die (not illustrated) or the like.

In the example of FIG. 2, corner portions a1, a2, a3, and a4 of the chip C_{M} correspond to corner portions b1, b2, b3, and b4 of the chip C_{P}, respectively.

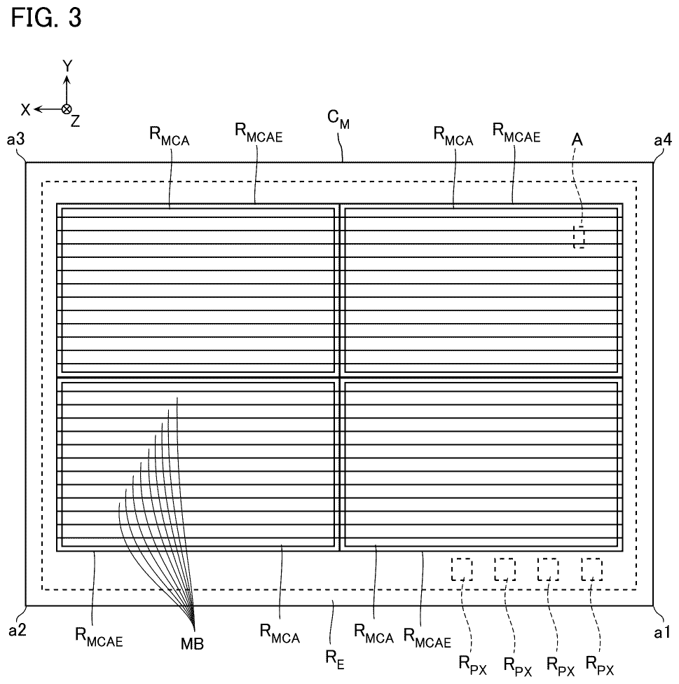

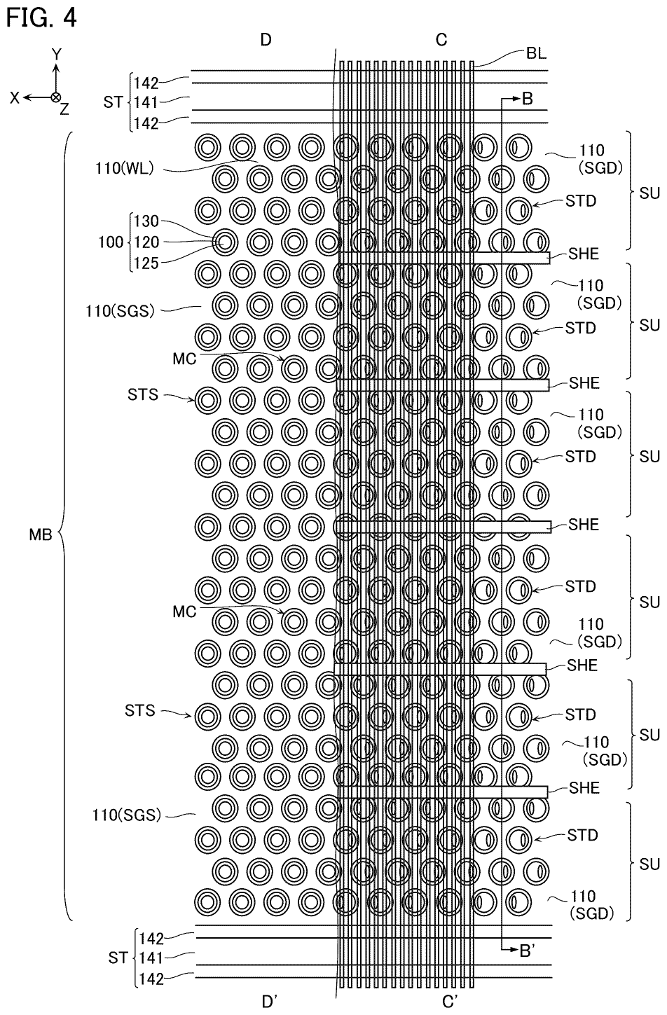

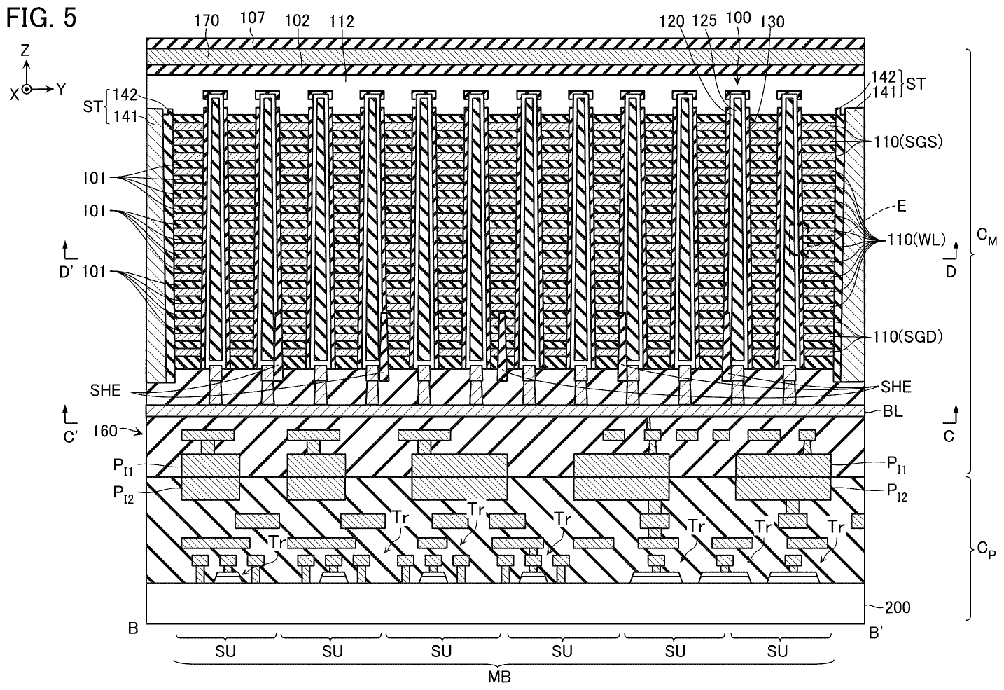

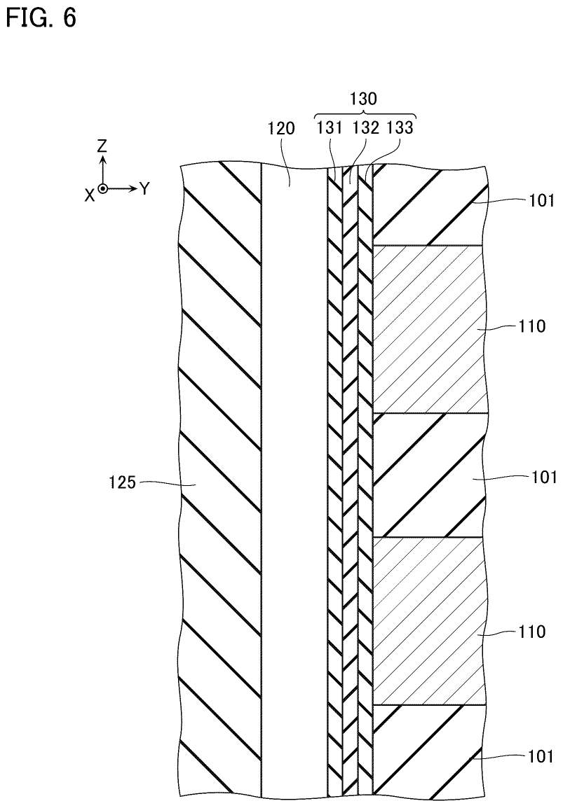

FIG. 3 is a schematic bottom view illustrating a configuration of the chip C_{M}. FIG. 4 is a schematic enlarged bottom view illustrating a configuration of a part indicated by A of FIG. 3. FIG. 4 illustrates plan views of a structure of FIG. 5 taken along the line C-C′ and the line D-D′ viewed in an arrow direction and arranged in the X-direction. FIG. 5 is a schematic cross-sectional view of the memory die MD taken along the line B-B′ of FIG. 4 viewed in an arrow direction. FIG. 6 is a schematic enlarged cross-sectional view of a configuration of a part indicated by E of FIG. 5.

### [Structure of Chip C_{M}]

For example, as illustrated in FIG. 3, the chip C_{M} includes four memory cell array regions R_{MCA} arranged in the X-direction and the Y-direction, memory cell array outer peripheral regions R_{MCAE} disposed along outer peripheries of the memory cell array regions R_{MCA}, a plurality of bonding pad electrode regions Rex corresponding to the plurality of bonding pad electrodes P_{X}, and an edge seal region RE disposed along an outer edge portion of the chip C_{M}.

The memory cell array region R_{MCA} includes a plurality of memory blocks MB arranged in the Y-direction. Between the memory blocks MB adjacent in the Y-direction, for example, as illustrated in FIG. 4 and FIG. 5, inter-block structures ST extending in the X-direction and the Z-direction are each disposed. The memory cell array region R_{MCA} includes a conductive layer 112 disposed on an upper surface of the plurality of memory blocks MB and the plurality of inter-block structures ST. A wiring layer 160 is disposed below these plurality of memory blocks MB. A wiring layer 170 is disposed above the conductive layer 112 via an insulating layer 102. An insulating layer 107 is disposed above the wiring layer 170.

As illustrated in FIG. 5, the memory block MB includes a plurality of conductive layers 110 arranged in the Z-direction, and a plurality of memory structures 100 extending in the Z-direction.

Each of the plurality of conductive layers 110 is an approximately plate-shaped conductive layer extending in the X-direction and the Y-direction. The conductive layer 110 may include a stacked film of a barrier conductive film, such as titanium nitride (TiN), and a metal film, such as tungsten (W), or the like. The conductive layer 110 may contain, for example, polycrystalline silicon or the like containing N-type impurities, such as phosphorus (P), or P-type impurities, such as boron (B). Between the plurality of conductive layers 110 arranged in the Z-direction, insulating layers 101 of silicon oxide (SiO₂) or the like are disposed.

Among the plurality of conductive layers 110, one or a plurality of conductive layers 110 positioned at uppermost layers function as the source select gate lines SGS and the gate electrodes of the plurality of source select transistors STS (FIG. 1) connected to the source select gate lines SGS. Hereinafter, such a conductive layer 110 is referred to as a conductive layer 110 (SGS) in some cases.

Among the plurality of conductive layers 110, one or a plurality of conductive layers 110 positioned at lowermost layers function as the drain select gate lines SGD and the gate electrodes of the plurality of drain select transistors STD (FIG. 1) connected to the drain select gate lines SGD. Hereinafter, such a conductive layer 110 is referred to as a conductive layer 110 (SGD) in some cases.

Among the plurality of conductive layers 110, a plurality of conductive layers 110 disposed between the conductive layers 110 (SGS) and the conductive layers 110 (SGD) function as the word lines WL and the gate electrodes of the plurality of memory cells MC (FIG. 1) connected to the word lines WL. Hereinafter, such a conductive layer 110 is referred to as a conductive layer 110 (WL) in some cases.

The memory structure 100 includes a semiconductor layer 120 extending in the Z-direction, and a gate insulating film 130 disposed between the plurality of conductive layers 110 and the semiconductor layer 120. One or a plurality of the source select transistors STS (FIG. 1) are configured at positions opposed to the conductive layers 110 (SGS) of the memory structure 100. One or a plurality of the drain select transistors STD (FIG. 1) are configured at positions opposed to the conductive layers 110 (SGD) of the memory structure 100. The plurality of memory cells MC (FIG. 1) are configured at positions opposed to the conductive layers 110 (WL) of the memory structure 100.

For example, as illustrated in FIG. 4, the memory structures 100 are arranged in the X-direction and the Y-direction in a predetermined pattern. The semiconductor layer 120 of the memory structure 100 functions as, for example, channel regions or the like of the plurality of memory cells. The semiconductor layer 120 includes, for example, single-crystal silicon (Si) or the like. The semiconductor layer 120 may contain impurities described later. For example, as illustrated in FIG. 5, the semiconductor layer 120 has an approximately closed-bottomed cylindrical shape, and an insulating layer 125 of silicon oxide or the like is disposed in a center portion of the semiconductor layer 120. The semiconductor layer 120 has an outer peripheral surface opposed to the conductive layers 110. The gate insulating film 130 is disposed between the semiconductor layer 120 and the conductive layers 110.

On the uppermost insulating layer 101, the conductive layer 112 of polycrystalline silicon (Si) or the like is disposed. In an upper end portion of the semiconductor layer 120, an impurity region containing N-type impurities, such as phosphorus (P), or P-type impurities, such as boron (B), is disposed. The upper end portion of the semiconductor layer 120 is covered with the gate insulating film 130. The gate insulating film 130 is partially removed, and a side surface of the upper end portion of the semiconductor layer 120 is partially exposed and electrically connected to the conductive layer 112.

An impurity region containing N-type impurities, such as phosphorus (P), is disposed on a lower end portion of the semiconductor layer 120. This impurity region covers a lower end of the insulating layer 125. This impurity region is electrically connected to the bit line BL. The bit line BL is electrically connected to the configuration inside the chip C_{P} via the above-described first bonding electrode Pr.

The gate insulating film 130 has an approximately cylindrical shape that covers the outer peripheral surface of the semiconductor layer 120. The gate insulating film 130 includes, for example, as illustrated in FIG. 6, a tunnel insulating film 131, an electric charge accumulating film 132, and a block insulating film 133, which are stacked between the semiconductor layer 120 and the conductive layers 110. The tunnel insulating film 131 and the block insulating film 133 are, for example, insulating films of silicon oxide (SiO₂) or the like. The electric charge accumulating film 132 is, for example, a film of silicon nitride (Si₃N₄) or the like that can accumulate electric charge. The tunnel insulating film 131, the electric charge accumulating film 132, and the block insulating film 133 each have an approximately cylindrical shape, and extend in the Z-direction along the outer peripheral surface of the semiconductor layer 120.

FIG. 6 illustrates an example in which the gate insulating film 130 includes the electric charge accumulating film 132 of silicon nitride or the like. However, the gate insulating film 130 may include, for example, a floating gate of polycrystalline silicon or the like containing N-type or P-type impurities.

For example, as illustrated in FIG. 4 and FIG. 5, the inter-block structure ST extends in the X-direction and the Z-direction, and separates the plurality of conductive layers 110 and the plurality of insulating layers 101 in the Y-direction for each memory block MB. The inter-block structure ST includes, for example, a conductive layer 141 extending in the X-direction and the Z-direction, and insulating layers 142 of silicon oxide (SiO₂) or the like disposed on side surfaces in the Y-direction of the conductive layer 141. The conductive layer 141 may include, for example, a stacked film of a barrier conductive film, such as titanium nitride (TiN), and a metal film, such as tungsten (W), or the like. The conductive layer 141 functions as, for example, a part of the source line. The conductive layer 141 has an upper end portion positioned above an upper surface of the uppermost insulating layer 101. The upper end portion of the conductive layer 141 is electrically connected to the conductive layer 112.

The conductive layer 112 may contain, for example, polycrystalline silicon or the like containing N-type impurities, such as phosphorus (P), or P-type impurities, such as boron (B). The conductive layer 112 functions as, for example, a part of the source line. The conductive layer 112 is in contact with the upper surface of the insulating layer 101, the upper end portion of the semiconductor layer 120, and the upper end portion of the conductive layer 141.

The conductive layers 110 (SGD) are separated in the Y-direction for each string unit SU by inter-string unit insulating layers SHE. Therefore, the conductive layer 110 (SGD) has a width in the Y-direction smaller than those of the other conductive layers 110 (SGS), 110 (WL). Each of the conductive layers 110 (SGD) is electrically independent for each string unit SU.

In this example, as illustrated in FIG. 4, the five inter-string unit insulating layers SHE are disposed between the inter-block structures ST. The inter-string unit insulating layer SHE at a center in the Y-direction is disposed so as to be overlapped with a row of dummy memory structures 100 arranged in the X-direction at a center in the Y-direction of the memory block MB. The other inter-string unit insulating layers SHE are disposed between rows of the memory structures 100 that are adjacent in the Y-direction and arranged in the X-direction such that the other inter-string unit insulating layers SHE are in contact with these rows of the memory structures 100.

### [Structure of Chip C_{P}]

For example, as illustrated in FIG. 5, the chip C_{P} includes a substrate 200 and a plurality of transistors Tr disposed on a surface of the substrate 200. These plurality of transistors Tr are connected to the configurations inside the chip C_{M} via the above-described second bonding electrodes P_{I2}, and function as the peripheral circuit PC used for controlling the memory cell array MCA. For example, in a read operation, this peripheral circuit PC applies a voltage to a current path including the bit line BL, the semiconductor layer 120, the conductive layer 110, the conductive layer 112, and the conductive layer 141, and determines data stored in the memory cell corresponding to whether a current flows or not, or the like.

In reading (or writing) of data to the memory cell MC, the peripheral circuit PC applies a driving voltage to the conductive layers 110 (SGD) corresponding to the string unit SU to be accessed, and turns on only the drain select transistor STD of the selected one string unit SU. In reading (or writing) of data to the memory cell MC, the peripheral circuit PC may apply a driving voltage to the conductive layers 110 (SGS) of one including the selected string unit SU, while the peripheral circuit PC may turn off the source select transistor STS connected to the conductive layers 110 (SGS) of the other. This makes the memory cells MC not involved in the read operation a floating state.

### [Manufacturing Method]

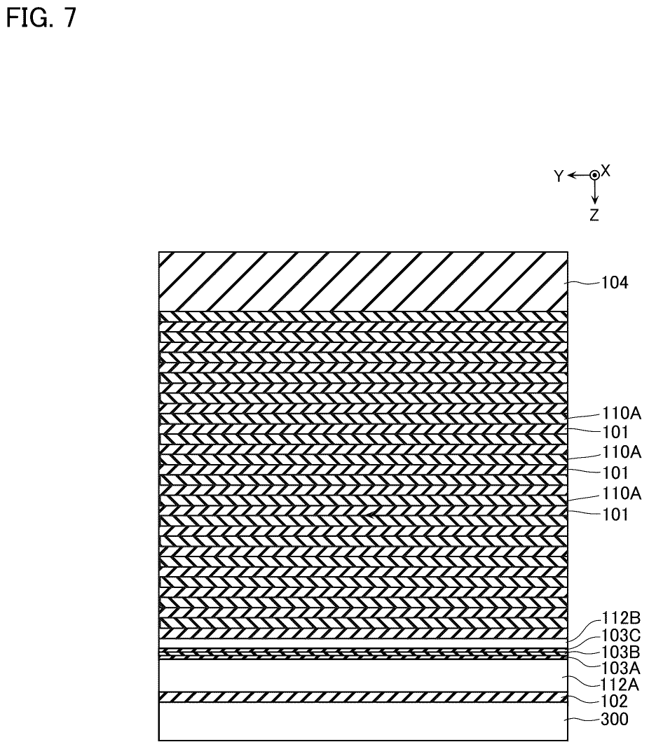

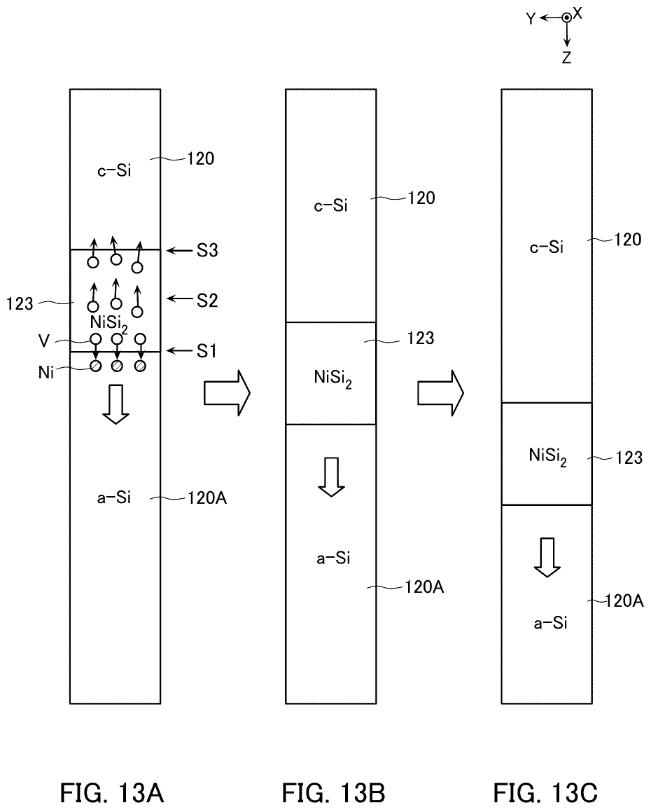

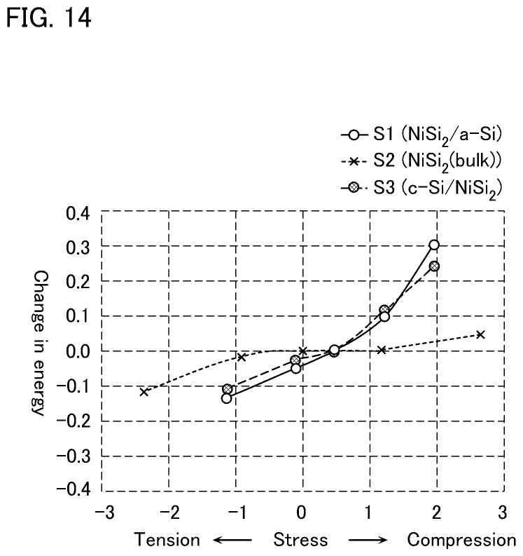

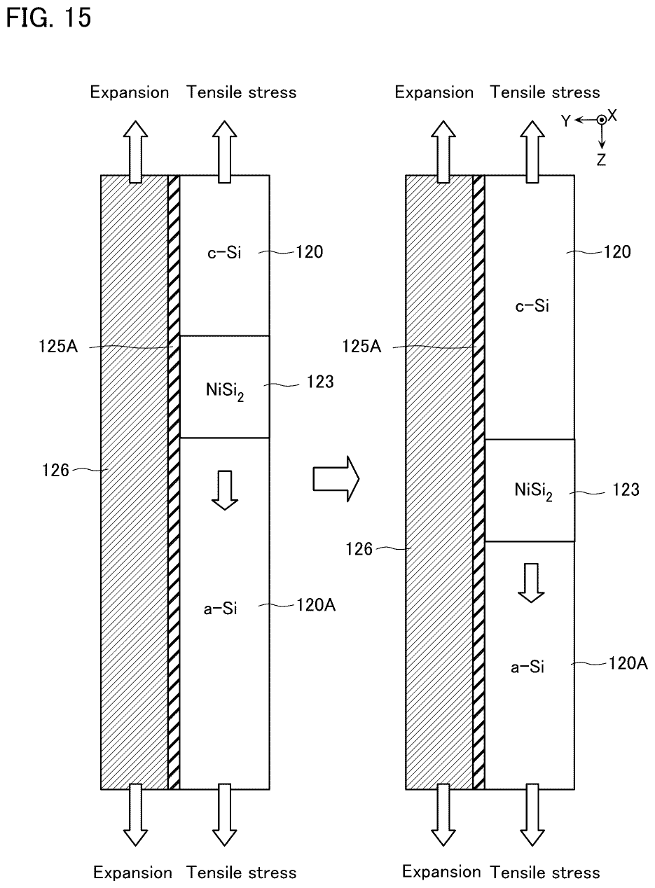

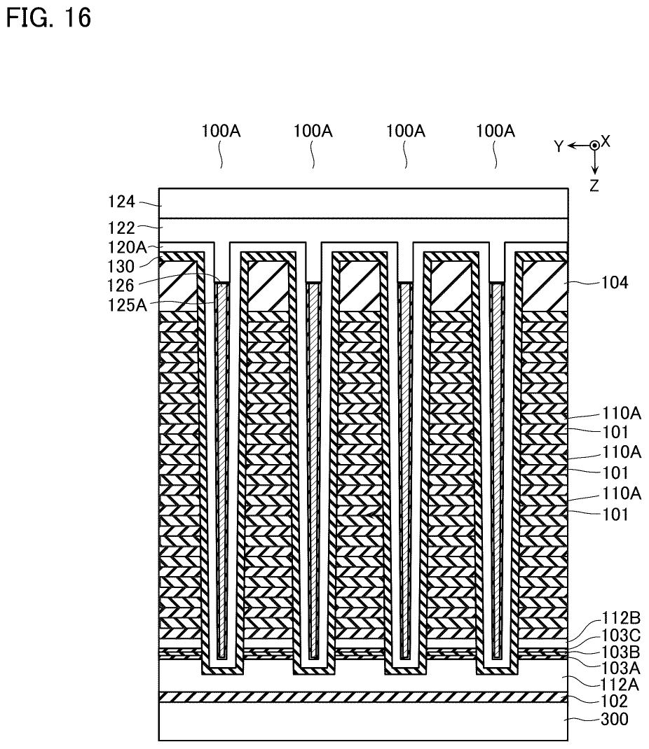

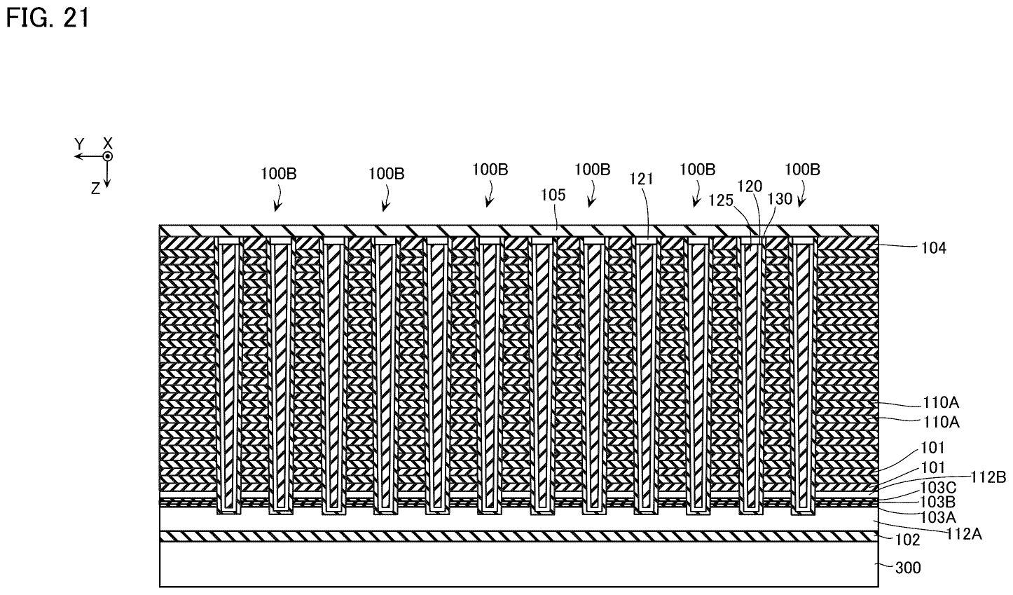

Next, with reference to FIG. 7 to FIG. 28, a method of manufacturing the memory die MD is described. FIG. 7 to FIG. 28 are diagrams for describing the manufacturing method. FIG. 7 to FIG. 12, and FIG. 16 to FIG. 20 illustrate cross-sectional surfaces corresponding to a part of FIG. 5, and FIG. 21 to FIG. 28 illustrate cross-sectional surfaces corresponding to FIG. 5. FIG. 13A, FIG. 13B, FIG. 13C, and FIG. 15 are schematic cross-sectional views for describing an operation of the manufacturing method. FIG. 14 is a graph for describing the effect of the manufacturing method.

In the manufacture of the memory die MD according to the embodiment, for example, as illustrated in FIG. 7, the insulating layer 102 of silicon oxide (SiO₂) or the like is formed on a substrate 300. For example, this process is performed by a method, such as Chemical Vapor Deposition (CVD). Next, a conductive layer 112A of silicon or the like, a sacrifice layer 103A of silicon oxide (SiO₂) or the like, a sacrifice layer 103B of silicon nitride (SiN) or the like, a sacrifice layer 103C of silicon oxide (SiO₂) or the like, and a conductive layer 112B of silicon or the like are formed on the insulating layer 102. The conductive layers 112A, 112B may contain, for example, polycrystalline silicon or the like containing N-type impurities, such as phosphorus (P), or P-type impurities, such as boron (B). Next, a plurality of insulating layers 101 of silicon oxide (SiO₂) or the like and a plurality of sacrifice layers 110A (first sacrifice layer) of silicon nitride (SiN) or the like are alternately formed on the conductive layer 112B. For example, these processes are performed by a method, such as CVD. Next, a cover insulating layer 104 is formed on the uppermost insulating layer 101. For example, this process is performed by a method, such as CVD.

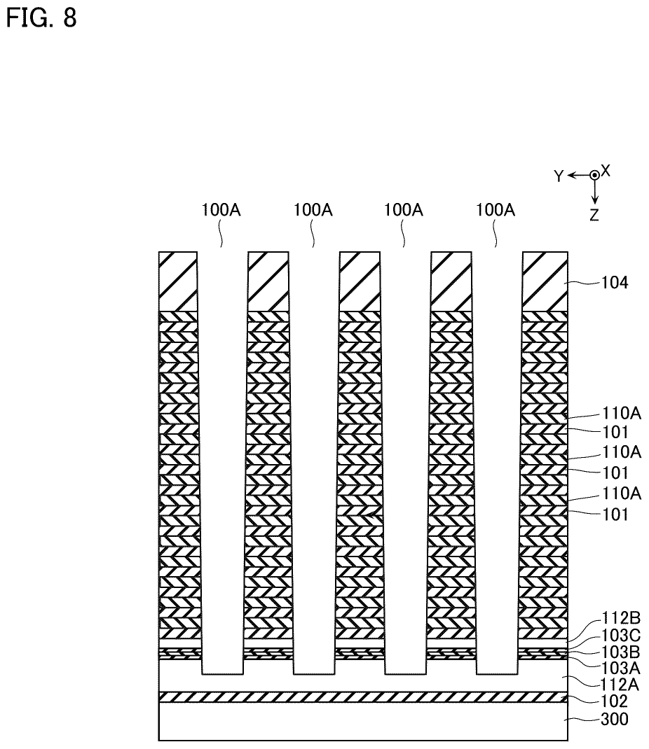

Next, for example, as illustrated in FIG. 8, using a mask (not illustrated), a plurality of memory holes 100A are formed at positions corresponding to the memory structures 100. The memory hole 100A extends in the Z-direction, penetrates the plurality of insulating layers 101, the plurality of sacrifice layers 110A, the conductive layer 112B, and the sacrifice layers 103C, 103B, 103A, and reaches the middle of the conductive layer 112A. For example, this process is performed by a method, such as Reactive Ion Etching (RIE).

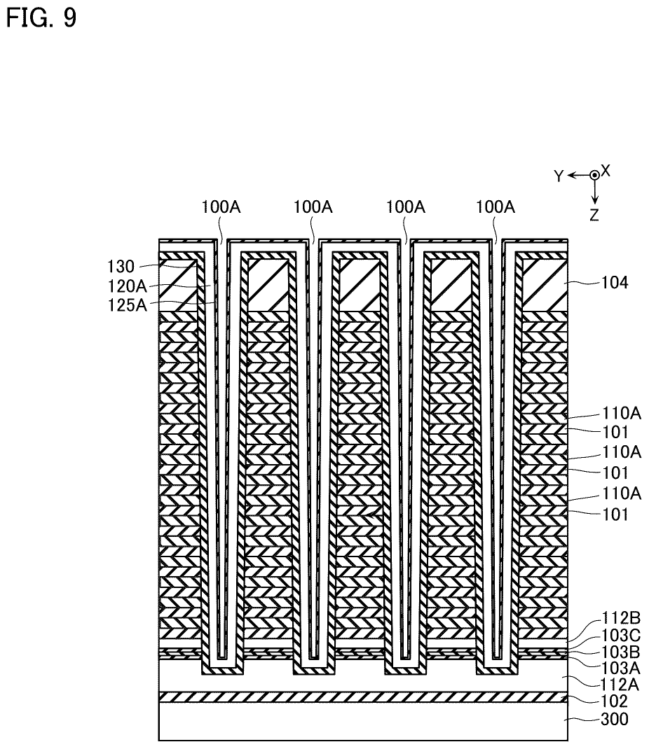

Next, for example, as illustrated in FIG. 9, the gate insulating film 130 (the tunnel insulating film 131, the electric charge accumulating film 132, and the block insulating film 133), a semiconductor layer 120A, and an insulating layer 125A are formed on an upper surface of the cover insulating layer 104 and an inner peripheral surface of the memory hole 100A. The semiconductor layer 120A contains, for example, amorphous silicon (a-Si) or the like. The insulating layer 125A contains, for example, silicon oxide (SiO₂) or the like. For example, the semiconductor layer 120A and the insulating layer 125A are formed by CVD or the like. Prior to forming the gate insulating film 130 on the inner peripheral surface of the memory hole 100A, insulating layers of silicon oxide (SiO₂) or the like may be formed on the respective parts exposed to the memory hole 100A of the conductive layer 112A and the conductive layer 112B by, for example, thermal oxidation or the like.

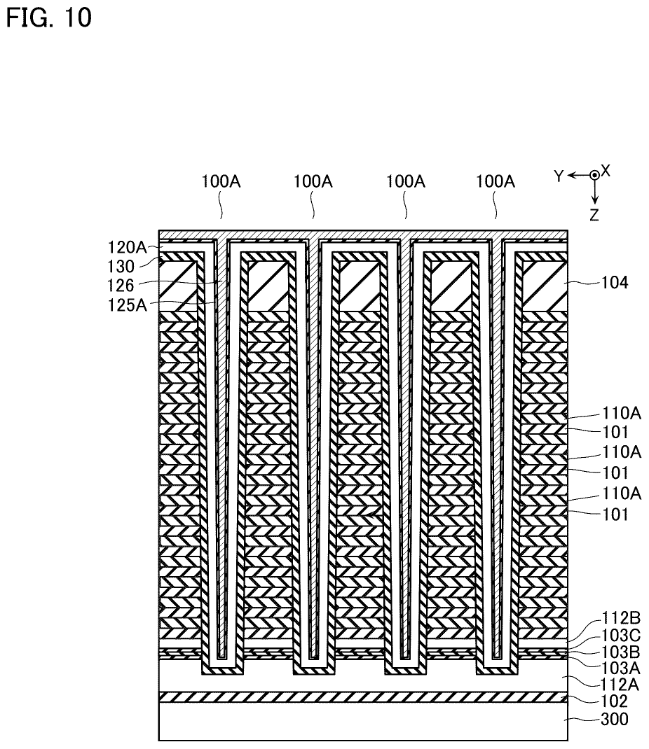

Next, for example, as illustrated in FIG. 10, a sacrifice core 126 is generated inside the insulating layer 125A formed in the memory hole 100A. The sacrifice core 126 contains a metal material, a metal compound material, or the like having a linear expansion coefficient larger than that of silicon (Si). For example, the sacrifice core 126 contains a metal material containing at least one metallic element selected from the group consisting of zinc (Zn), indium (In), silver (Ag), gold (Au), cobalt (Co), zirconium (Zr), aluminum (Al), titanium (Ti), yttrium (Y), and copper (Cu), or at least one metal compound material selected from the group consisting of Zro₂, Al₂O₃, Tic, TiNi, Y₂O₃, and AlN.

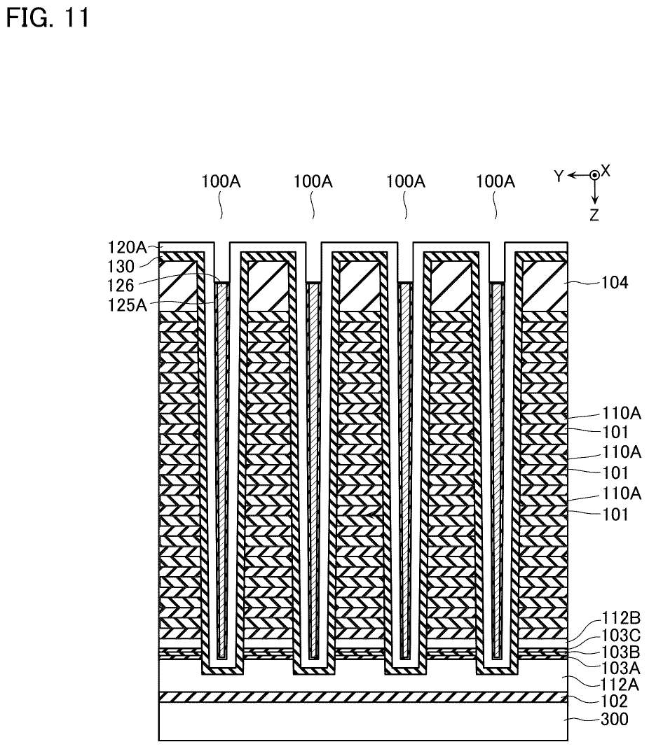

Next, for example, as illustrated in FIG. 11, upper surfaces of the sacrifice core 126 and the insulating layer 125A are removed up to an intermediate height position of the cover insulating layer 104. For example, this process is performed by a method, such as wet etching or RIE.

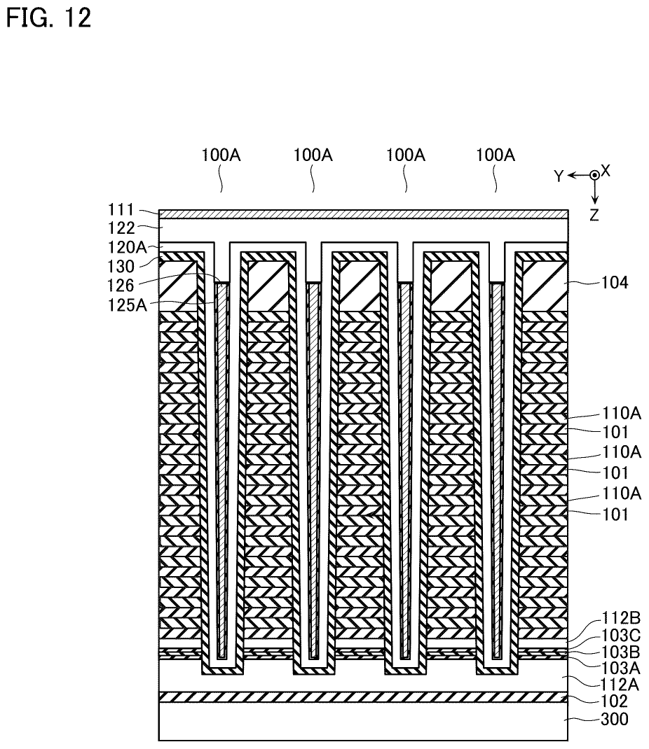

Next, for example, as illustrated in FIG. 12, a semiconductor layer 122 is formed on the semiconductor layer 120A and the sacrifice core 126. The semiconductor layer 122 contains, for example, amorphous silicon (a-Si) or the like. A metal layer 111 is formed on the semiconductor layer 122. The metal layer 111 contains at least one metallic element that is able to form silicide with silicon, such as nickel, palladium, and cobalt. Hereinafter, an example in which the metal layer 111 is nickel is described. For example, the semiconductor layer 122 and the metal layer 111 are formed by a method, such as CVD.

Next, the semiconductor layer 120A is crystallized by Metal Induced Lateral Crystallization (MILC) method. Specifically, a long-time crystallization annealing at 400° C. to 800° C. is performed on the chip C_{M}. This causes nickel atoms contained in the metal layer 111 to diffuse into the amorphous silicon of the semiconductor layer 122, and crystals of nickel disilicide (NiSi₂) grow in the semiconductor layer 122. While the crystallization annealing continues, these crystals move in the semiconductor layer 122, while accelerating the diffusion of Ni and the crystallization of silicon, to reach the semiconductor layer 120A, and further move within the semiconductor layer 120A from one end portion to the other end portion in the Z-direction.

FIG. 13A, FIG. 13B, and FIG. 13C are diagrams for describing the above-described MILC method in detail, and are schematic enlarged cross-sectional views of the semiconductor layer 120A.

As illustrated in FIG. 13A, at an interface S1 between the semiconductor layer 120A of amorphous silicon and a silicide layer 123, nickel atoms Ni in the silicide layer 123 diffuse into the semiconductor layer 120A, and form the silicide layer 123 at the diffused position. On the other hand, in an inside S2 of the silicide layer 123, vacancies V corresponding to the nickel atoms Ni diffused on the semiconductor layer 120A side are generated, and these vacancies V diffuse through the silicide layer 123 to reach an interface S3 between the silicide layer 123 and the semiconductor layer 120. At the interface S3, the vacancies V aggregates and silicon crystals grow. As illustrated in FIG. 13A, FIG. 13B, and FIG. 13C, in the process in which the silicide layer 123 moves from the one end side to the other end side of the semiconductor layer 120A, the semiconductor layer 120A of amorphous silicon is crystallized, thus forming the semiconductor layer 120 made of single-crystallized silicon. Here, the “single-crystallized silicon” does not mean to be limited to a perfect “single-crystal silicon”, but also includes “crystallized silicon” that is close to single-crystal silicon, with a larger maximum width of crystal grain than that of “polysilicon”.

The crystallization process by the MILC method described above requires heating for a long time. However, the longer the crystallization annealing time, the more easily amorphous silicon turns to polysilicon. Polysilicon has a resistance value higher than that of single-crystal silicon, causing a decrease in cell current.

To accelerate the speed of crystallization by the MILC method, it is effective to (1) facilitate the formation of the vacancies V, (2) accelerate the diffusion of the vacancies V, and (3) facilitate the disappearance of the vacancies V. According to the findings of the present inventors and the like, applying tensile stress to the semiconductor layer 120A in a progress direction of crystallization (Z-direction) is effective in accelerating the above-described (1) to (3).

FIG. 14 is a graph showing the relation between the stress in the progress direction of crystallization (Z-direction) applied to the semiconductor layer 120A and the change in energy required for the movement of Ni atoms. As can be clearly seen from FIG. 14, at all of the NiSi₂/a-Si interface S1, the inside S2 of NiSi₂ bulk, and the c-Si/NiSi₂ interface S3, the greater the magnitude of the applied tensile stress, the more easily the Ni atoms move. Therefore, in this embodiment, a metal material or a metal compound material having a linear expansion coefficient larger than that of silicon is used as the sacrifice core 126. FIG. 15 is a schematic enlarged cross-sectional view of parts of the semiconductor layer 120 and the sacrifice core 126 during the crystallization annealing process. As illustrated in FIG. 15, during the crystallization annealing, the sacrifice core 126 expands in the progress direction of crystallization (Z-direction), and as a result, tensile stress is applied to the semiconductor layers 120, 120A in the progress direction of crystallization. Thus, the progress of crystallization is accelerated, and the single-crystallized semiconductor layer 120 is generated. During the crystallization annealing, the insulating layer 125A functions as a shield layer for suppressing a reaction between the metallic element contained in the sacrifice core 126 and the semiconductor layers 120, 120A.

After the crystallization annealing by the MILC method is completed, subsequently, as illustrated in FIG. 16, an adsorption layer 124 made of amorphous silicon is formed on the crystallized semiconductor layer 122. This process is performed by a method, such as CVD.

Next, a heat treatment is performed. Thus, nickel atoms remained in the semiconductor layer 120 are adsorbed by the adsorption layer 124. After the heat treatment, a small amount of the first metallic element (for example, nickel element) that can form silicide, which has not been adsorbed in the adsorption process, may remain in the semiconductor layer 120 as impurities. Also, a small amount of the second metallic element contained in the sacrifice core 126 that has moved to the semiconductor layer 120 across the insulating layer 125A may remain in the semiconductor layer 120. A content ratio of the second metallic element is smaller than a content ratio of the first metallic element.

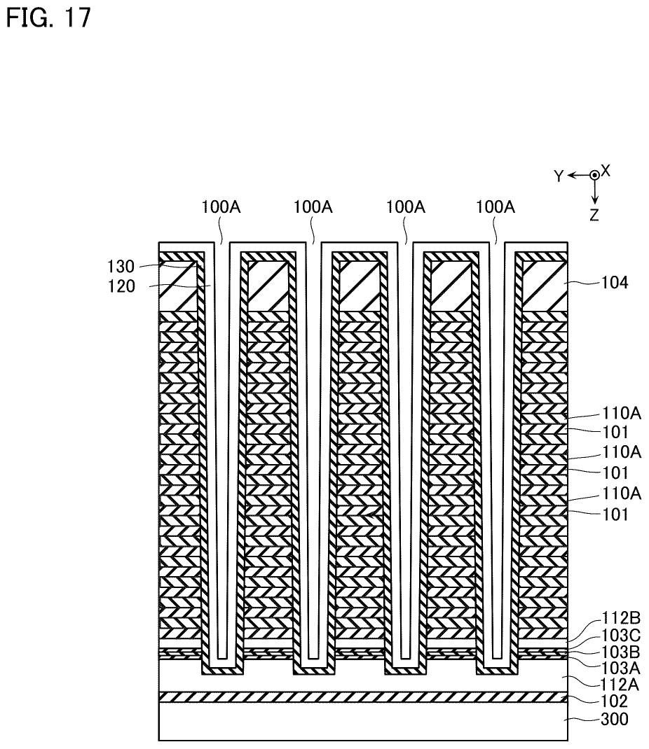

Next, as illustrated in FIG. 17, the adsorption layer 124, the semiconductor layer 122, the sacrifice core 126, and the insulating layer 125A are removed. For example, this process is performed by a method, such as RIE or wet etching.

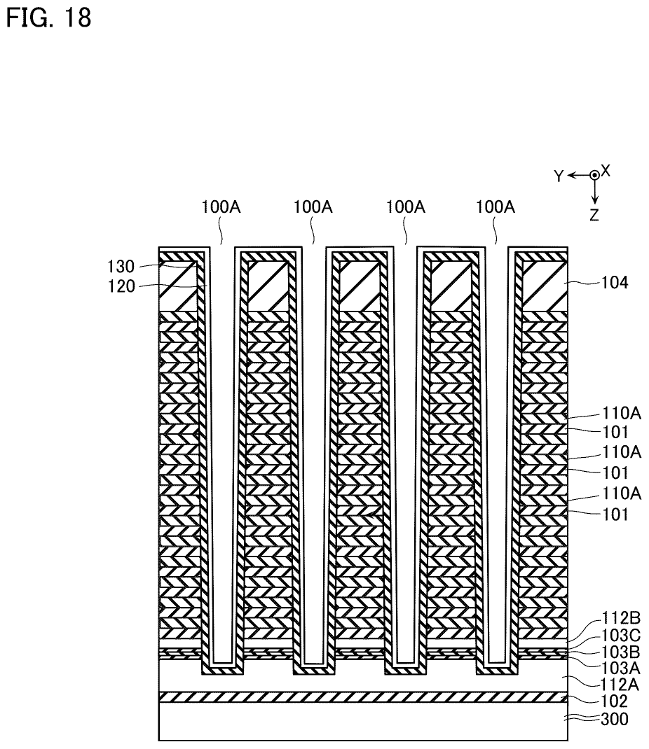

Next, as illustrated in FIG. 18, a slimming process is performed on the semiconductor layer 120. Thus, a thickness of the semiconductor layer 120 decreases. For example, this process is performed by a method, such as wet etching.

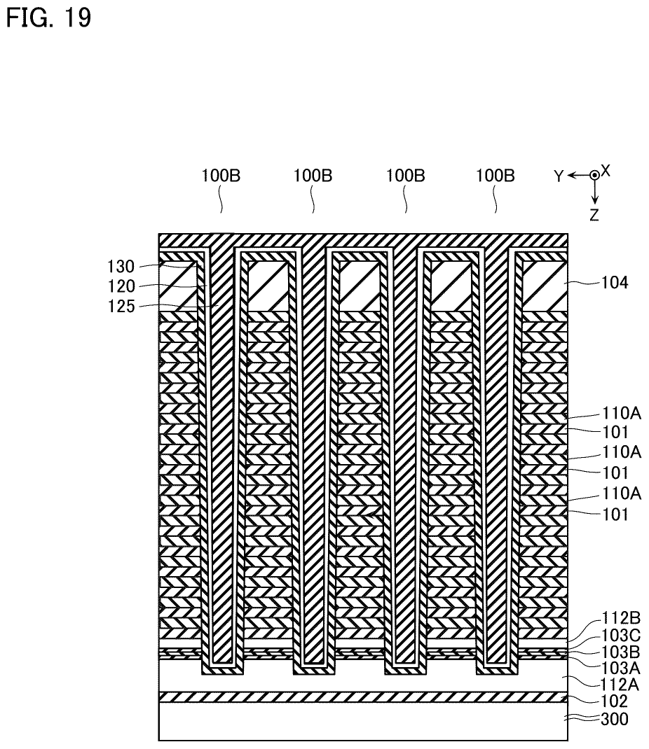

Next, as illustrated in FIG. 19, the insulating layer 125 is formed at a center of the semiconductor layer 120. Thus, a memory structure 100B is formed. For example, this process is performed by a method, such as CVD.

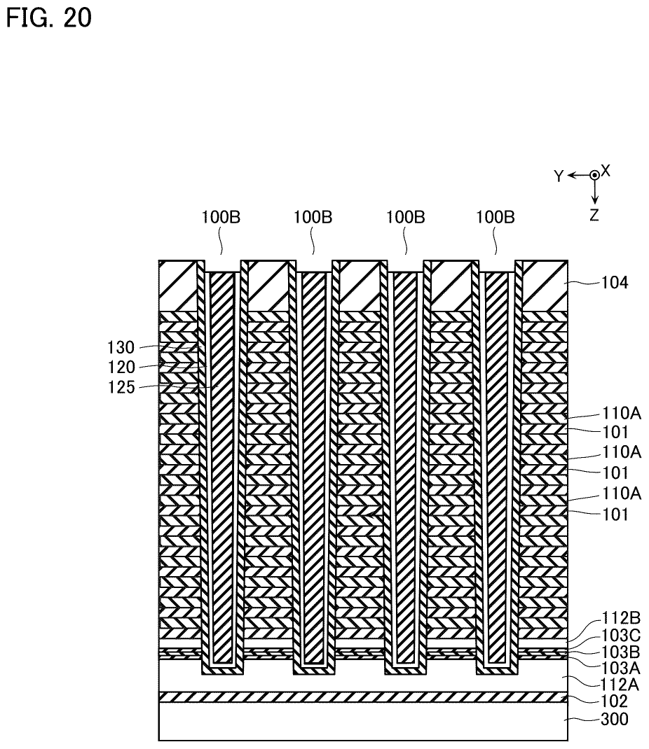

Next, for example, as illustrated in FIG. 20, the insulating layer 125, the semiconductor layer 120, and the gate insulating film 130 are partially removed to expose the cover insulating layer 104 positioned in the uppermost layer. Upper end portions of the semiconductor layer 120 and the insulating layer 125 are dug down below the upper surface of the cover insulating layer 104. For example, this process is performed by a method, such as RIE.

Next, for example, as illustrated in FIG. 21, on upper ends of the semiconductor layer 120 and the insulating layer 125, a semiconductor layer 121 is formed. The semiconductor layer 121 contains, for example, amorphous silicon containing N-type impurities, such as phosphorus (P). For example, this process is performed by a method, such as CVD. Next, for example, the semiconductor layer 121 is partially removed by a method, such as RIE, thereby exposing the cover insulating layer 104. Next, an insulating layer 105 is formed on the cover insulating layer 104 and the semiconductor layer 121. For example, this process is performed by a method, such as CVD.

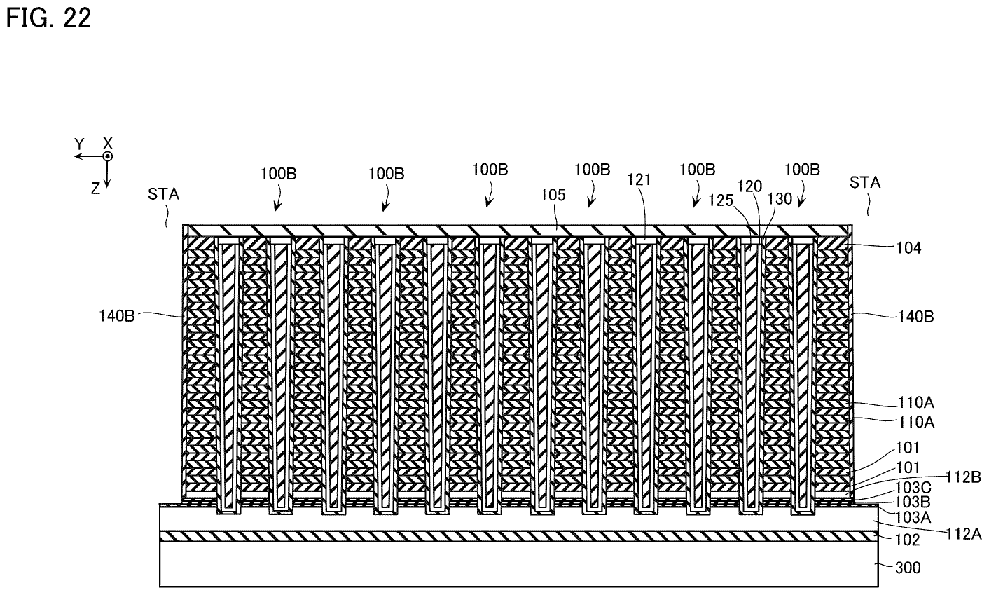

Next, for example, as illustrated in FIG. 22, trenches STA are formed at positions at which the inter-block structures ST are to be formed. The trench STA extends in the Z-direction and the X-direction, separates the insulating layer 105, the cover insulating layer 104, the insulating layers 101, the sacrifice layers 110A, the conductive layer 112B, the sacrifice layer 103C, and the sacrifice layer 103B in the Y-direction, and exposes an upper surface of the sacrifice layer 103A. For example, this process is performed by a method, such as RIE. Next, protective films 140B of silicon nitride or the like are formed on side surfaces in the Y-direction of the trench STA. For example, this process is performed by forming an insulating film of silicon nitride or the like on the side surfaces in the Y-direction and a bottom surface of the trench STA by a method, such as CVD, and subsequently removing a part covering the bottom surface of the trench STA of this insulating film by a method, such as RIE.

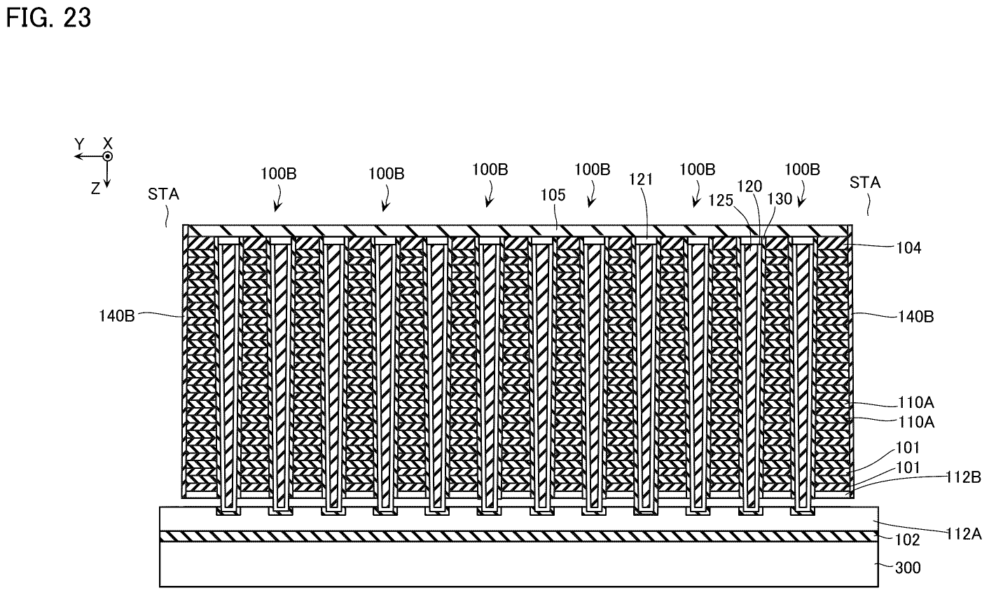

Next, for example, as illustrated in FIG. 23, the sacrifice layers 103A, 103B, 103C and a part of the gate insulating film 130 are removed, thereby exposing a part of the semiconductor layer 120. For example, this process is performed by a method, such as wet etching.

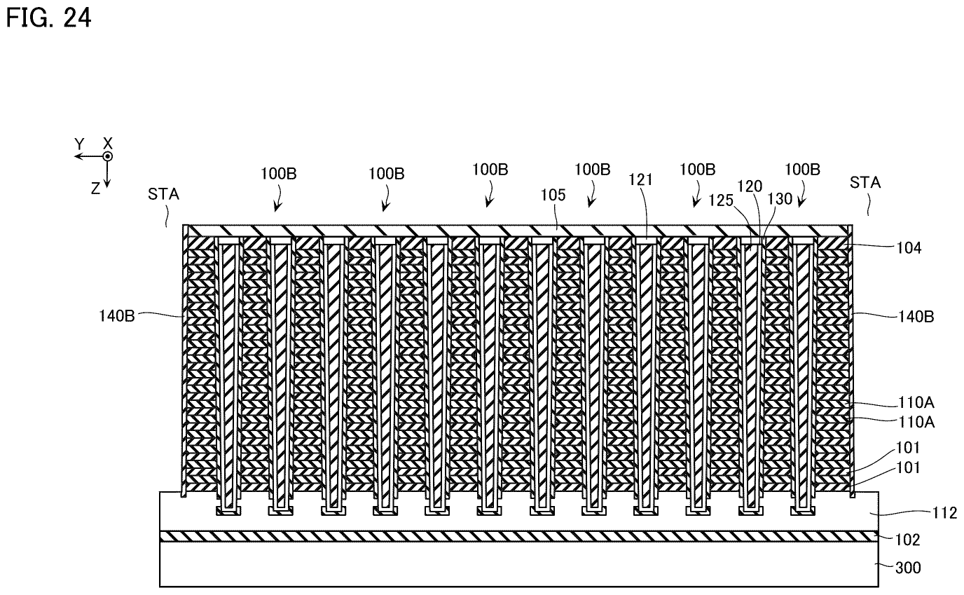

Next, for example, as illustrated in FIG. 24, a semiconductor layer is formed on the part where the sacrifice layers 103A, 103B, 103C and a part of the gate insulating film 130 have been removed, thus forming a conductive layer 112 by the additionally formed semiconductor layer and the conductive layers 112A, 112B. The semiconductor layer formed inside the trench STA is removed. For example, this process is performed by epitaxial growth and a method, such as RIE.

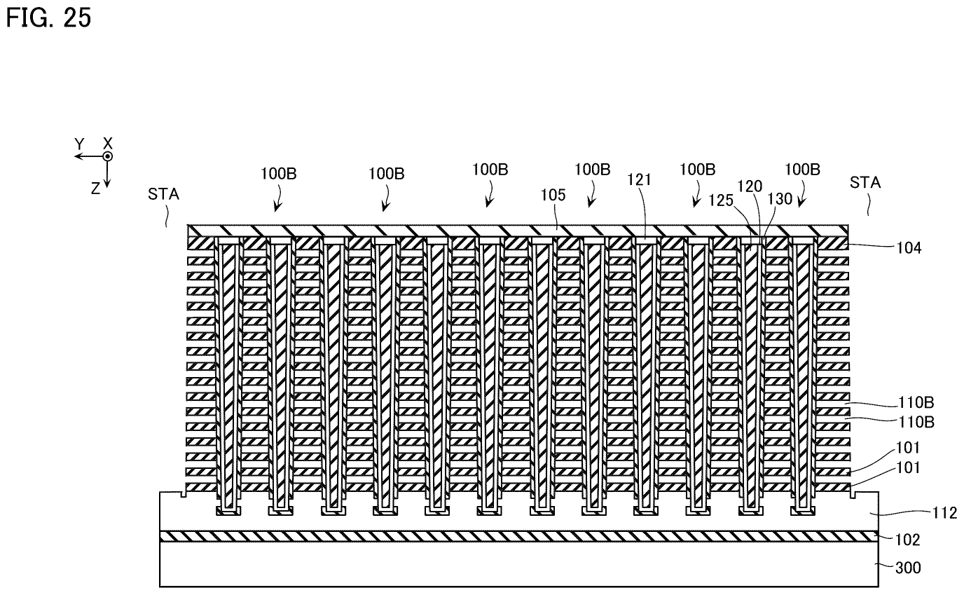

Next, for example, as illustrated in FIG. 25, the protective film 140B is removed, and the sacrifice layers 110A are removed via the trench STA. For example, this process is performed by a method, such as wet etching. Accordingly, a hollow structure including a plurality of insulating layers 101 arranged in the Z-direction and the memory structure 100B supporting these insulating layers 101 is formed.

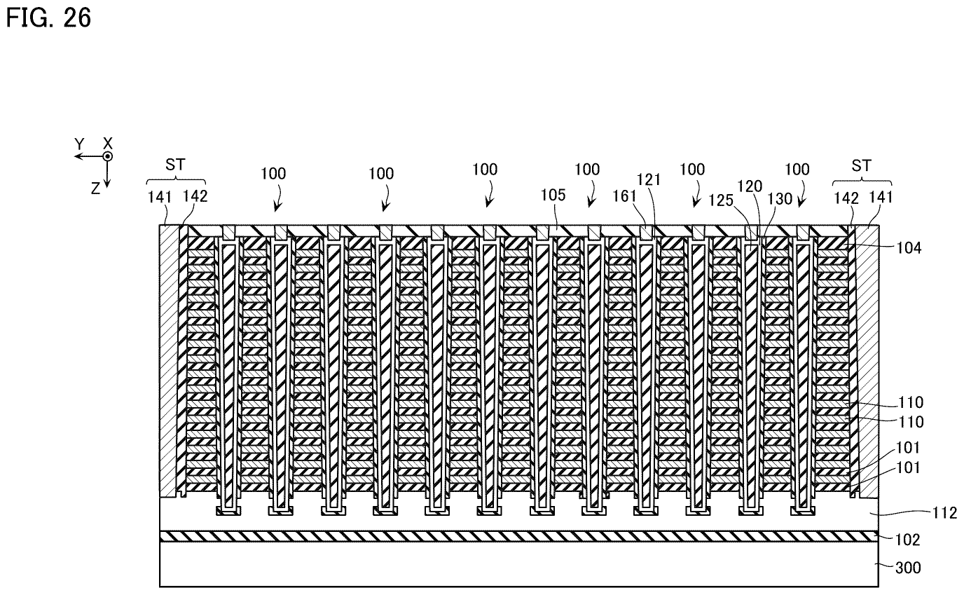

Next, for example, as illustrated in FIG. 26, the conductive layers 110 are formed in the hollow parts. For example, this process is performed by a method, such as CVD. Next, the insulating layer 142 constituting the inter-block structure ST is formed inside the trench STA. Next, the conductive layer 141 is formed at a center in the Y-direction of the insulating layer 142, and a contact 161 is formed. For example, these processes are performed by methods, such as CVD and RIE. The insulating layer 142 extends from the insulating layer 105 to the conductive layer 112. The conductive layer 141 penetrates the insulating layer 105, and its lower end portion is electrically connected to the conductive layer 112. The contact 161 penetrates the insulating layer 105, and is electrically connected to the semiconductor layer 121 of the memory structure 100B.

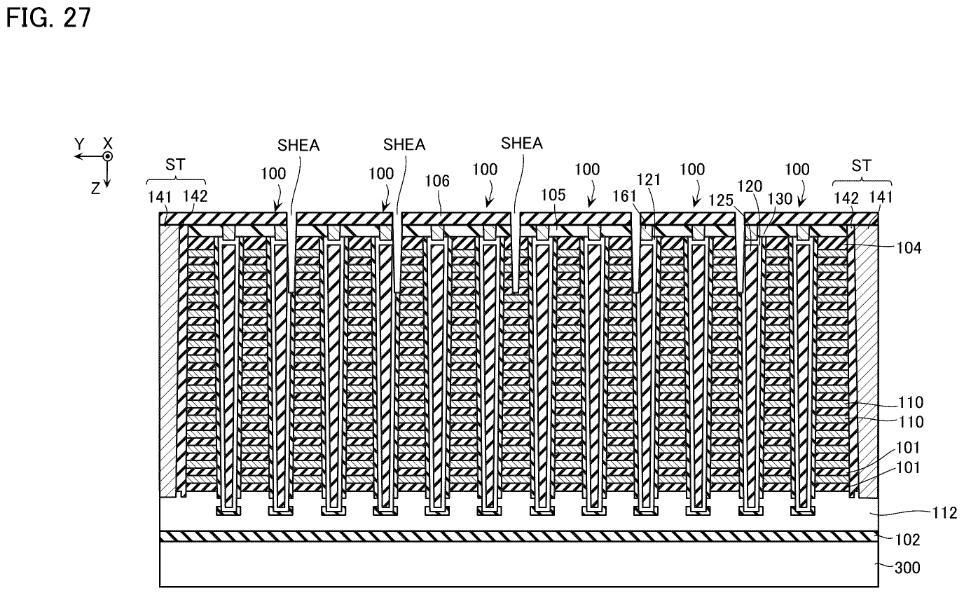

Next, for example, as illustrated in FIG. 27, a resist is formed on the insulating layer 105 to form a mask 106 by a method of photoetching. Using the mask 106, trenches SHEA separating the insulating layer 105, the cover insulating layer 104, the insulating layers 101, and the conductive layers 110 (SGD) in the Y-direction are formed. For example, this process is performed by a method, such as RIE.

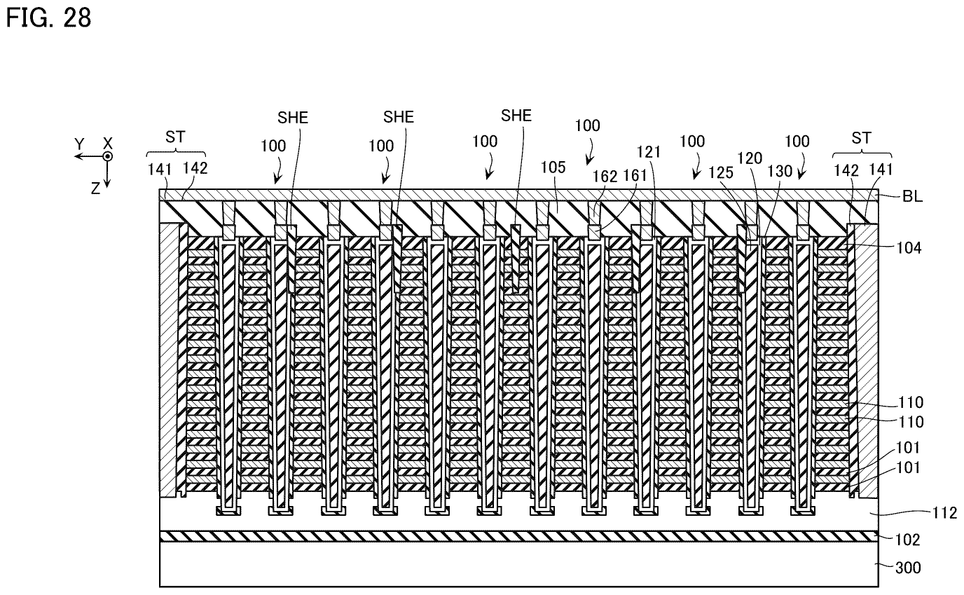

Next, for example, as illustrated in FIG. 28, the inter-string unit insulating layers SHE are formed inside the trenches SHEA. Next, the insulating layer 105 is stacked over the insulating layer 105. Next, the insulating layer 105 is etched in a predetermined pattern, thus forming contacts 162 connected to the contacts 161 and a bit line BL.

Afterward, the insulating layer 105 is stacked over the bit line BL, and further, the wiring layer 160 illustrated in FIG. 5 is formed, thereby manufacturing the chip C_{M}.

### [Effect]

According to the embodiment, since tensile stress can be applied to the semiconductor layer 120A using thermal expansion of the sacrifice core 126 during the MILC process, the crystallization speed of the semiconductor layer 120A can be improved. Thus, a semiconductor memory device with preferred characteristics having a well-crystallized semiconductor layer as a channel can be provided.

### Second Embodiment

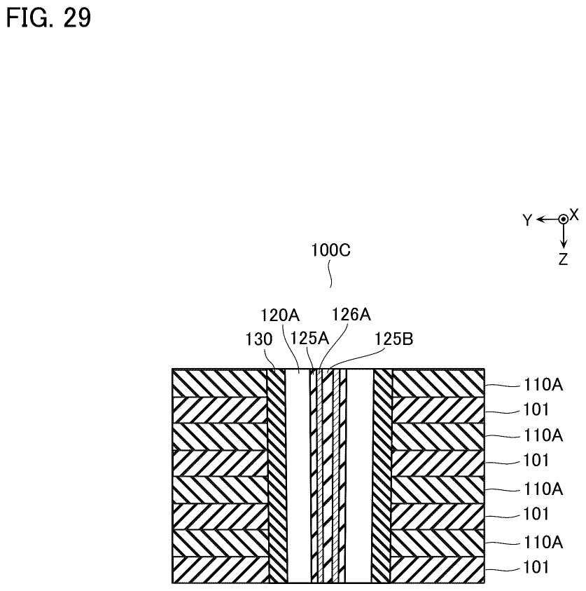

FIG. 29 is a schematic cross-sectional view for describing a manufacturing method of a semiconductor memory device according to the second embodiment.

In the second embodiment, as illustrated in FIG. 29, instead of the sacrifice core 126 used in the first embodiment, a sacrifice layer 126A (second sacrifice layer) is generated inside the insulating layer 125A formed in a memory hole 100C. An insulating layer 125B is formed inside the sacrifice layer 126A. The sacrifice layer 126A contains a metal material, a metal compound material, or the like having a linear expansion coefficient larger than that of silicon (Si). For example, the sacrifice layer 126A contains a metal material containing at least one metallic element selected from the group consisting of zinc (Zn), indium (In), silver (Ag), gold (Au), cobalt (Co), zirconium (Zr), aluminum (Al), titanium (Ti), yttrium (Y), and copper (Cu), or at least one metal compound material selected from the group consisting of Zro₂, Al₂O₃, Tic, TiNi, Y₂O₃, and AlN.

Next, similarly to the first embodiment, upper surfaces of the insulating layer 125B, the sacrifice layer 126A, and the insulating layer 125A are removed up to an intermediate height position of the cover insulating layer 104, and the semiconductor layer 122 is formed on the semiconductor layer 120A and the sacrifice layer 126A. The semiconductor layer 122 contains, for example, amorphous silicon (a-Si) or the like. The metal layer 111 is formed on the semiconductor layer 122. The metal layer 111 contains a metallic element that is able to form silicide with silicon, such as nickel. Next, the semiconductor layer 120A is crystallized by the MILC method.

Next, similarly to the first embodiment, the adsorption layer 124 made of amorphous silicon is formed on the crystallized semiconductor layer 122, and then a heat treatment is performed. Thus, nickel atoms remained in the semiconductor layer 120 are adsorbed by the adsorption layer 124. After the heat treatment, a small amount of the first metallic element (for example, nickel element) that can form silicide, which has not been adsorbed in the adsorption process, may remain in the semiconductor layer 120 as impurities. Also, a small amount of the second metallic element contained in the sacrifice layer 126A that has moved to the semiconductor layer 120 across the insulating layer 125A may remain in the semiconductor layer 120. A content ratio of the second metallic element is smaller than a content ratio of the first metallic element.

Next, similarly to the first embodiment, the adsorption layer 124, the semiconductor layer 122, the sacrifice layer 126A, the insulating layer 125B, and the insulating layer 125A are removed. Subsequent processes are the same as in the first embodiment.

Also in the second embodiment, since tensile stress can be applied to the semiconductor layer 120A using thermal expansion of the sacrifice layer 126A during the MILC process, the crystallization speed of the semiconductor layer 120A can be improved. Thus, a semiconductor memory device with preferred characteristics having a well-crystallized semiconductor layer as a channel can be provided.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of first conductive layers arranged in a first direction and extending in a second direction intersecting with the first direction and a third direction intersecting with the first direction and the second direction; and
a memory structure extending in the first direction, the memory structure including a first semiconductor layer opposed to the plurality of first conductive layers and a gate insulating layer disposed between the first semiconductor layer and the plurality of first conductive layers, wherein
the first semiconductor layer contains single-crystallized silicon and an impurity, and
the impurity contains:
a first metallic element that is able to form silicide; and
a second metallic element constituting a metal material having a linear expansion coefficient larger than a linear expansion coefficient of a silicon material.

2. The semiconductor memory device according to claim 1, wherein
the first metallic element contains at least one selected from the group consisting of nickel, palladium, and cobalt.

3. The semiconductor memory device according to claim 2, wherein
the first metallic element is nickel.

4. The semiconductor memory device according to claim 1, wherein
the second metallic element contains at least one selected from the group consisting of zinc, indium, silver, gold, cobalt, zirconium, aluminum, titanium, yttrium, and copper.

5. The semiconductor memory device according to claim 1, wherein
a content ratio of the second metallic element contained in the impurity is smaller than a content ratio of the first metallic element.

6. A method of manufacturing a semiconductor memory device, comprising:
stacking a first insulating layer and a first sacrifice layer in alternation in a first direction;
forming a memory hole extending in the first direction in the first insulating layer and the first sacrifice layer;
forming a second insulating layer inside the memory hole;
forming a first semiconductor layer containing amorphous silicon inside the second insulating layer in the memory hole;
forming a metal layer on one end side in the first direction of the first semiconductor layer, the metal layer containing a first metallic element that is able to form silicide;
performing a first heat treatment to single-crystallize amorphous silicon in the first semiconductor layer;
after forming the first semiconductor layer, and before forming the metal layer,
forming a third insulating layer inside the first semiconductor layer; and
forming a sacrifice core inside the third insulating layer, the sacrifice core containing a second metallic element having a linear expansion coefficient larger than a linear expansion coefficient of the first semiconductor layer; and
after performing the first heat treatment, removing the sacrifice core and the third insulating layer and forming a fourth insulating layer inside the first semiconductor layer.

7. The method of manufacturing the semiconductor memory device according to claim 6, wherein
the first metallic element contains at least one selected from the group consisting of nickel, palladium, and cobalt.

8. The method of manufacturing the semiconductor memory device according to claim 7, wherein
the first metallic element is nickel.

9. The method of manufacturing the semiconductor memory device according to claim 6, wherein
the sacrifice core contains a metal material containing at least one metallic element selected from the group consisting of zinc, indium, silver, gold, cobalt, zirconium, aluminum, titanium, yttrium, and copper, or at least one metal compound material selected from the group consisting of Zro₂, Al₂O₃, Tic, TiNi, Y₂O₃, and AlN.

10. The method of manufacturing the semiconductor memory device according to claim 6, comprising:
before forming the metal layer, forming a second semiconductor layer on the one end side in the first direction of the first semiconductor layer; and
forming the metal layer on the second semiconductor layer.

11. The method of manufacturing the semiconductor memory device according to claim 6, comprising:
after the first heat treatment, forming a third semiconductor layer on the one end side in the first direction of the first semiconductor layer; and
performing a second heat treatment to adsorb the first metallic element onto the third semiconductor layer.

12. The method of manufacturing the semiconductor memory device according to claim 6, comprising
after removing the sacrifice core and the third insulating layer, and before forming the fourth insulating layer, performing a slimming process on the first semiconductor layer.

13. A method of manufacturing a semiconductor memory device, comprising:
stacking a first insulating layer and a first sacrifice layer in alternation in a first direction;
forming a memory hole extending in the first direction in the first insulating layer and the first sacrifice layer;
forming a second insulating layer inside the memory hole;
forming a first semiconductor layer containing amorphous silicon inside the second insulating layer in the memory hole;
forming a metal layer on one end side in the first direction of the first semiconductor layer, the metal layer containing a first metallic element that is able to form silicide;
performing a first heat treatment to single-crystallize amorphous silicon in the first semiconductor layer;
after forming the first semiconductor layer, and before performing the first heat treatment, forming a second sacrifice layer extending in the first direction at a proximity of the first semiconductor layer, the second sacrifice layer containing a second metallic element having a linear expansion coefficient larger than a linear expansion coefficient of the first semiconductor layer; and
after performing the first heat treatment, removing the second sacrifice layer.

14. The method of manufacturing the semiconductor memory device according claim 13, comprising:
after forming the first semiconductor layer, and before forming the metal layer, forming a third insulating layer inside the first semiconductor layer; and
forming the second sacrifice layer inside the third insulating layer.

15. The method of manufacturing the semiconductor memory device according claim 14, comprising:
after performing the first heat treatment, removing the second sacrifice layer and the third insulating layer; and
forming a fourth insulating layer inside the first semiconductor layer.

16. The method of manufacturing the semiconductor memory device according to claim 13, comprising:
before forming the metal layer, forming a second semiconductor layer on the one end side in the first direction of the first semiconductor layer; and
forming the metal layer on the second semiconductor layer.

17. The method of manufacturing the semiconductor memory device according to claim 16, comprising:
after the first heat treatment, forming a third semiconductor layer on the one end side in the first direction of the first semiconductor layer; and
performing a second heat treatment to adsorb the first metallic element onto the third semiconductor layer.

18. The method of manufacturing the semiconductor memory device according to claim 15, comprising
after removing the second sacrifice layer and the third insulating layer, and before forming the fourth insulating layer, performing a slimming process on the first semiconductor layer.

19. The method of manufacturing the semiconductor memory device according to claim 13, wherein
the first metallic element is nickel.

20. The method of manufacturing the semiconductor memory device according to claim 13, wherein
the second sacrifice layer contains a metal material containing at least one metallic element selected from the group consisting of zinc, indium, silver, gold, cobalt, zirconium, aluminum, titanium, yttrium, and copper, or at least one metal compound material selected from the group consisting of Zro₂, Al₂O₃, Tic, TiNi, Y₂O₃, and AlN.
